(19) United States
(12) Patent Application Publication
(10) Pub. No.: US 2018/0024200 A1
(43) Pub. Date: Jan. 25, 2018

(54) SECONDARY BATTERY STATE-OF-CHARGE ESTIMATING DEVICE AND SECONDARY BATTERY STATE-OF-CHARGE ESTIMATING METHOD

(71) Applicant: Panasonic Intellectual Property Management Co., Ltd., Osaka (JP)

(72) Inventor: SATORU HIWA, Kanagawa (JP)

(21) Appl. No.: 15/547,735

(22) PCT Filed: Feb. 3, 2016
(86) PCT No.: PCT/JP2016/000545

§ 371 Date: Jul. 31, 2017

(30) Foreign Application Priority Data
Feb. 13, 2015 (JP) 2015-026704

(51) Int. Cl. G01R 31/36

(52) U.S. Cl. CPC G01R 31/3651

(57) ABSTRACT

A state-of-charge (SOC) estimating device includes detector, a current-integration SOC calculator, a state estimation SOC calculator, a convergence determiner, and SOC selector. The detector detects a charge/discharge current and a voltage between terminals of a secondary battery. The current-integration SOC calculator calculates a state-of-charge value of the secondary battery by a current integration method. The state estimation SOC calculator calculates a state-of-charge value of the secondary battery by a state estimation method. The convergence determiner determines the convergence of the state estimation by the state estimation SOC calculator. The SOC selector selects a state-of-charge of the secondary battery from the calculated state-of-charge values according to the determination result of the convergence determiner. The convergence determiner determines non-convergence when the secondary battery is charging and at the same time the change of a given charging parameter has been determined smaller than a given threshold.

### CROSS-REFERENCE TO RELATED APPLICATION

This application is a U.S. national stage application of the PCT International Application No. PCT/JP2016/000545 filed on Feb. 3, 2016, which claims the benefit of foreign priority of Japanese patent application No. 2015-026704 filed on Feb. 13, 2015, the contents all of which are incorporated herein by reference.

### BACKGROUND

### Technical Field

The present disclosure relates to a secondary battery state-of-charge estimating device and a secondary battery state-of-charge estimating method for estimating a state-of-charge of a secondary battery.

### Description of the Related Art

A secondary battery charge control system equipped to an electric vehicle (EV), a hybrid electric vehicle (HEV), or a gasoline-powered vehicle is required to estimate a state-of-charge (SOC) of a secondary battery with high accuracy to maintain the secondary battery in an intended state of charge.

A typical example of a state-of-charge estimating method is a current integration method. In the current integration method, a state-of-charge of a secondary battery at a certain time point is given as an initial value, and a charge/discharge current of the secondary battery is time-integrated to determine a state-of-charge. The system has map data in advance indicating the relationship between open-circuit voltage (OCV) values and values of state-of-charge of the secondary battery. The initial value is determined by measuring a present open-circuit voltage of the secondary battery and reading the state-of-charge corresponding to the measured voltage.

Examples of a method of estimating a state-of-charge include a state space estimation method based on an iterative least squares technique, and based on an adaptive filter (e.g., a Kalman filter, a particle filter) to estimate an internal state of a secondary battery (refer to PTL 1, for example). Estimating an internal state with a small error allows the system to estimate a state-of-charge with high accuracy.

As a method of estimating a state-of-charge, there is known a method using a learning method such as a neural network to estimate an internal state of a secondary battery (refer to PTLs 2 through 4, for example).

A method for estimating a state-of-charge using a state space estimation method or a learning method such as a neural network to estimate an internal state of a secondary battery is called a state estimation method.

### CITATION LIST

### Patent Literature

PTL 1: Japanese Patent Unexamined Publication No. 2013-072677

PTL 2: Japanese Patent Unexamined Publication No. 2008-232758

PTL 3: Japanese Patent Unexamined Publication No. H09-243716

PTL 4: Japanese Patent Unexamined Publication No. 2003-249271

### BRIEF SUMMARY

The present disclosure provides a secondary battery state-of-charge estimating device and a secondary battery state-of-charge estimating method for estimating a state-of-charge of a secondary battery with high accuracy.

A secondary battery state-of-charge estimating device according to one aspect of the disclosure includes a detector, a current-integration SOC calculator, a state estimation SOC calculator, a convergence determiner, and an SOC selector. The detector detects a charge/discharge current and a voltage between terminals (an inter-terminal voltage) of a secondary battery. The current-integration SOC calculator calculates a state-of-charge value of the secondary battery based on detection results of the detector by a current integration method. The state estimation SOC calculator calculates a state-of-charge value of the secondary battery based on detection results of the detector by a state estimation method. The convergence determiner determines the convergence of the state estimation by the state estimation SOC calculator. The SOC selector selects a state-of-charge value calculated by the current-integration SOC calculator or that calculated by the state estimation SOC calculator, as an estimated value of a state-of-charge of the secondary battery, according to the determination result of the convergence determiner. The convergence determiner determines as the state estimation is non-convergent when the secondary battery is being charged and at the same time change of a given charging parameter is determined smaller than a given threshold.

In the secondary battery state-of-charge estimating method according to one aspect of the disclosure, a charge/discharge current and an inter-terminal voltage of a secondary battery are first detected. Then, a state-of-charge value of the secondary battery is calculated based on the detected charge/discharge current and the detected inter-terminal voltage, by a current integration method. Further, a state-of-charge value of the secondary battery is calculated based on the detected charge/discharge current and the detected inter-terminal voltage, by a state estimation method. Then, the convergence of the state estimation when calculating a state-of-charge of the secondary battery is determined. Furthermore, selection is made from the state-of-charge value calculated by the current integration method or that by the state estimation method, as an estimated value of the state-of-charge value of the secondary battery, according to the determination result of the convergence. In determining the convergence, the state estimation is determined as non-convergent if the secondary battery is being charged and at the same time change of a given charging parameter is determined smaller than a given threshold.

The disclosure allows estimating a state-of-charge of a secondary battery with high accuracy.

### BRIEF DESCRIPTION OF THE SEVERAL VIEWS OF THE DRAWINGS

FIG. 1 is a block diagram illustrating a state-of-charge estimating device according to an exemplary embodiment of the present disclosure.

FIG. 2 is a diagram illustrating an example equivalent circuit model of a secondary battery used in a state estimation method.

FIG. 3 is a flowchart illustrating a process flow of the state-of-charge estimating device according to the embodiment.

FIG. 4 is a flowchart illustrating detailed steps for determining convergence of state estimation.

FIG. 5 is a time chart illustrating operation of the state-of-charge estimating device according to the embodiment.

FIG. 6 is a time chart illustrating detail of a determination period for constant-voltage charging in FIG. 5.

### DETAILED DESCRIPTION

Prior to the description of an embodiment of the present disclosure, a description is simply made of problems in conventional technologies. When reading an inter-terminal voltage of a secondary battery, the voltage value may contain a polarization component due to the internal resistance of the secondary battery and/or due to the concentration distribution of the electrolyte. Accordingly, a current integration method cannot accurately measure an open-circuit voltage, resulting in an offset error contained in the estimated state-of-charge. Additionally, the current integration method cannot allow for fluctuations in the polarization component during charging/discharging, resulting in a cumulative offset error that may increase the error of the estimated state-of-charge.

Meanwhile, using a state estimation method to estimate a state-of-charge of the secondary battery allows the estimation of a state-of-charge while removing the effect of the polarization component of the secondary battery.

In the estimation of a state-of-charge by the state estimation method, however, an estimated value of each parameter of the equivalent circuit model of the secondary battery usually does not converge for a while after starting the state estimation or while the charge/discharge current and the inter-terminal voltage of the secondary battery are fluctuating in a small range. An estimated value of each parameter out of convergence prevents a state-of-charge from being accurately estimated. The state where an estimated value of each parameter is not convergent is referred to as state estimation out of convergence.

Hereinafter, a description is made of the embodiment of the present disclosure with reference to drawings. The following embodiment is an example of an embodied technology of the present disclosure and does not limit the technological scope of the disclosure.

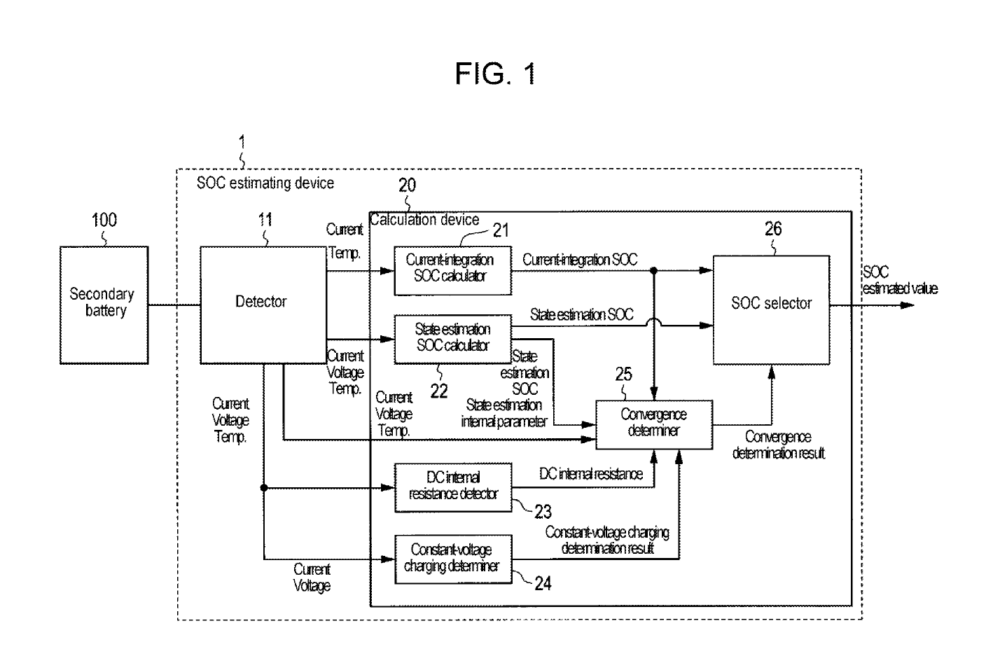

FIG. 1 is a block diagram of state-of-charge estimating device 1 according to the exemplary embodiment of the present disclosure.

State-of-charge estimating device 1 estimates a state-of-charge of secondary battery 100. Secondary battery 100 is incorporated to a vehicle for example. Secondary battery 100 is typically a lead-acid battery, especially one for idling stop system (ISS) used for an ISS vehicle. Secondary battery 100, however, may be of any type as long as it is chargeable and dischargeable.

State-of-charge estimating device 1 includes detector 11 and calculation device 20. Calculation device 20 includes current-integration SOC calculator 21, state estimation SOC calculator 22, DC internal resistance detector 23, constant-voltage charging determiner 24, convergence determiner 25, and SOC selector 26.

Detector 11 detects a charge/discharge current and an inter-terminal voltage of secondary battery 100 and outputs the detected values to calculation device 20. Besides, detector 11 may detect a temperature of secondary battery 100 to output the detected value to calculation device 20. Detector 11 performs the detection periodically in a given sampling period. The sampling period may be constant or variable according to a given function in response to conditions. In FIG. 1, a charge/discharge current and an inter-terminal voltage of secondary battery 100 are noted simply as current and voltage, respectively.

Calculation device 20 includes a central processing unit (CPU) that performs arithmetic processing, a memory that stores processing programs and control data for example, and a random access memory (RAM) that temporarily stores process results of the CPU, input data and the like. The function of each block of calculation device 20 is achieved by these hardware devices. Calculation device 20 is typically composed of a one-chip large scale integration (an LSI) or a circuit board, but not limited to these. Some blocks in calculation device 20 may be partly composed of a separate chip, or may be integrally structured with the electric control unit (ECU) on the vehicle.

Current-integration SOC calculator 21 calculates a state-of-charge (SOC) value of secondary battery 100 using a current integration method. Current-integration SOC calculator 21 first calculates an initial value of the state-of-charge when starting an integration process. The initial value of the state-of-charge is obtained from an inter-terminal voltage of secondary battery 100 using map data, for example. Map data represents the correspondence between open-circuit voltage values of secondary battery 100 and state-of-charge values, for example, which is determined by measurement or other manners in advance and retained by current-integration SOC calculator 21. When the initial value is obtained, current-integration SOC calculator 21 time-integrates the measured charge/discharge current, converts the result to a state-of-charge, then, integrates the resultant to the initial value, thus yields the state-of-charge at each time point. Each state-of-charge (referred to as “current-integration SOC” hereinafter) is sent to SOC selector 26 and convergence determiner 25.

State estimation SOC calculator 22 estimates an internal state of secondary battery 100 by a state space estimation method, which is one of state estimation methods, to estimate a state-of-charge. In this embodiment, an example of a state space estimation method is shown where a Kalman filter is used as an adaptive filter. As a state estimation method, however, a particle filter may be used as an adaptive filter, for example. Alternatively, an iterative least squares technique may be used in the state space estimation method. Besides, state estimation SOC calculator 22 may use a learning method such as a neural network to estimate the internal state of secondary battery 100 for estimating the state-of-charge.

State estimation SOC calculator 22 receives values of charge/discharge currents and inter-terminal voltages at discrete time intervals from detector 11, and then estimates an internal state of secondary battery 100, and calculates a state-of-charge value.

State estimation SOC calculator 22 sends the calculated state-of-charge value (referred to as “state estimation SOC” hereinafter) to SOC selector 26 and convergence determiner 25. Further, state estimation SOC calculator 22 sends an internal parameter (referred to as “state estimation internal parameter” hereinafter) obtained in estimating the internal state of secondary battery 100 to convergence determiner 25. A concrete example is given later of a calculating method of state estimation SOC calculator 22 and an internal parameter sent to convergence determiner 25.

DC internal resistance detector 23 receives input of values of a charge/discharge current, an inter-terminal voltage, and a temperature of secondary battery 100, from detector 11, and estimates the DC internal resistance of secondary battery 100. The estimated DC internal resistance is sent to convergence determiner 25. DC internal resistance detector 23 can estimate the DC internal resistance of secondary battery 100 using various methods widely known such as the state space estimation method.

Constant-voltage charging determiner 24 receives the values of a charge/discharge current and an inter-terminal voltage of secondary battery 100, from detector 11, and determines whether or not secondary battery 100 is in constant-voltage charging, based on the values. This determination method is described later. Constant-voltage charging determiner 24 sends this determination result to convergence determiner 25 as “constant-voltage charging determination result.”

Convergence determiner 25 receives the current-integration SOC, the state estimation SOC, the state estimation internal parameter, the DC internal resistance, and the constant-voltage charging determination result, from the above-described blocks. Convergence determiner 25 receives the values of the charge/discharge current, the inter-terminal voltage, and the temperature of secondary battery 100, from detector 11. Convergence determiner 25 determines whether or not the state estimation of an internal state of secondary battery 100 by state estimation SOC calculator 22 is convergent. Further details about this determination method are described later. Convergence determiner 25 sends the convergence determination result to SOC selector 26.

SOC selector 26 selects, based on the convergence determination result, the current-integration SOC or state estimation SOC, as a state-of-charge (referred to as “SOC estimated value”), which is an estimation result of state-of-charge estimating device 1, and outputs either of them.

State Estimation

Next, an example is shown of a method of calculating a state-of-charge by a state estimation method using a Kalman filter performed by state estimation SOC calculator 22. The subsequent description is an example of a state estimation method, and does not limited the state estimation method according to the disclosure.

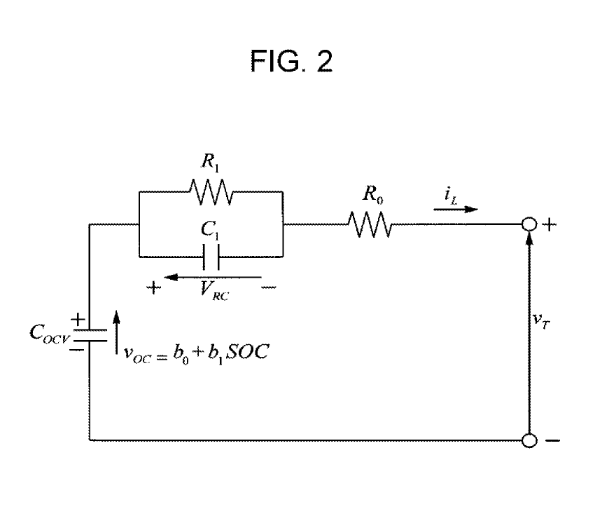

FIG. 2 illustrates an example equivalent circuit model of a secondary battery used for a state estimation method.

In state estimation SOC calculator 22, the internal model of secondary battery 100 is represented using the equivalent circuit model shown in FIG. 2. In FIG. 2, resistance R₀ represents an internal resistance component such as ohmic resistance and charge transfer resistance. Resistance R₁ and capacitance C₁ represent diffusion resistance polarization, and V_{RC} represents a polarization voltage. Capacity C_{OCV} represents battery capacity. Open-circuit voltage V_{OC} and a state-of-charge (SOC) corresponding to battery capacity C_{OCV} have the relationship of next expression (1). V_{T} represents an inter-terminal voltage of secondary battery 100. The item i_{L} represents a charge/discharge current of secondary battery 100.

v_{OC}=b₀+b₁SOC (1)

The state equation of the state space expression in discrete time using a Kalman filter is expressed as next expression (2), and the output equation of the state space expression is expressed as next expression (3). Here, x(k) represents a state vector; y(k) represents terminal voltage V_{T}; u(k) represents charge/discharge current i_{L}; v(k) represents system noise; w(k) represents observation noise; and k represents an ordinal number indicating discrete timing at which a detection result is obtained.

x(k+1)=A(k)×(k)+bᵤ(k)u(k)+b(k)v(k) (2)

y(k)=c^{T}(k)×(k)+d(k)u(k)+w(k) (3)

State vector x(k) of space expression in discrete time can be defined as next expression (4) for example.

$$x ( k ) = ( \begin{matrix}SOC ( k ) \\ {b}_{0} ( k ) \\ {V}_{RC} ( k )\end{matrix} ) \qquad ( 4 )$$

Each matrix and each vector of the discrete-time state-space expression can be defined as next expressions (5) through (9), where ΔT represents discrete time and Q_{R} represents the nominal capacity of secondary battery 100.

$$\begin{matrix}A ( k ) = A ( k - 1 ) = ( \begin{matrix}1 & 0 & 0 \\ 0 & 1 & 0 \\ 0 & 0 & 1 - \frac{Δ T}{{R}_{1} {C}_{1}}\end{matrix} ) & ( 5 ) \\ {b}_{u} ( k ) = {b}_{u} ( k - 1 ) = ( \begin{matrix}- \frac{Δ T}{{Q}_{R}} \\ 0 \\ \frac{Δ T}{{C}_{1}}\end{matrix} ) & ( 6 ) \\ c ( k ) = c ( k - 1 ) = ( \begin{matrix}{b}_{1} \\ 1 \\ - 1\end{matrix} ) & ( 7 ) \\ d ( k ) = d ( k - 1 ) = - {R}_{0} & ( 8 ) \\ b ( k ) = b ( k - 1 ) = 1 & ( 9 )\end{matrix}$$

State estimation SOC calculator 22, when starting calculation for state estimation, is first given with initial value x(0) of the state vector, and initial values σᵥ² and σ_{w}² of the dispersion of errors in the state vector and the detected values. The initial value of the state-of-charge (SOC) can be determined in the same way as the way used by current-integration SOC calculator 21. Other initial values and the initial value of the dispersion value have only to use values estimated in advance.

State estimation SOC calculator 22, when receiving the values of a charge/discharge current and an inter-terminal voltage of secondary battery 100 from detector 11, calculates an estimated value of advance state vector x̂⁻(k) and advance error covariance matrix P⁻(k) using next expressions (10) and (11), respectively, where the hat symbol “̂” indicates an estimated value, and the superscript negative symbol “·” represents an advance calculated value before detection.

\hat{x}⁻(k)=A(k−1)\hat{x}(k−1)+bᵤ(k−1)u(k−1) (10)

P⁻(k)=A(k−1)P(k−1)A^{T}(k−1)+σᵥ²b(k−1)b^{T}(k−1) (11)

State estimation SOC calculator 22 calculates Kalman gain g(k) when receiving the values of a charge/discharge current and an inter-terminal voltage of secondary battery 100 from detector 11. State estimation SOC calculator 22 uses state vector x̂⁻(k) calculated beforehand, error covariance matrix P⁻(k) calculated beforehand, and Kalman gain g(k), to calculate an estimated value of state vector x̂(k) and error covariance matrix P(k) which are updated by reflecting the detected values. The calculation can be made using next expressions (12) through (14) for example.

$$\begin{matrix}g ( k ) = \frac{{P}^{-} ( k ) c ( k )}{{c}^{T} ( k ) {P}^{-} ( k ) c ( k ) + {σ}_{w}^{2}} & ( 12 ) \\ \hat{x} ( k ) = {\hat{x}}^{-} ( k ) + g ( k ) ( y ( k ) - ( {c}^{T} ( k ) {\hat{x}}^{-} ( k ) + d ( k ) u ( k ) ) ) & ( 13 ) \\ P ( k ) = ( I - g ( k ) {c}^{T} ( k ) ) {P}^{-} ( k ) & ( 14 )\end{matrix}$$

State estimation SOC calculator 22 assigns state vector x̂(k) and error covariance matrix P(k) thus determined to a state vector and an error covariance matrix at discrete timing k after being updated.

State estimation SOC calculator 22 repeats calculating an advance state vector and an error covariance matrix described above; and calculating a Kalman gain and a state vector and an error covariance matrix after being updated, every time a detected value is input from detector 11. Then, state estimation SOC calculator 22 outputs the value of the SOC of the state vector as a state estimation SOC. State estimation SOC calculator 22 outputs error covariance matrix P(k) as a state estimation internal parameter to convergence determiner 25.

Error covariance matrix P(k) indicates the dispersion of errors in respective components of state vector x(k) in the diagonal components. In the above-described example, the first row and the first column of error covariance matrix P(k) represents the dispersion value of errors in the state-of-charge (SOC(k)); the second row and the second column represents the dispersion value of errors in intercept b₀(k) of the relational expression between open-circuit voltage V_{OC} and state-of-charge SOC; and the third row and the third column represents the dispersion value of errors in polarization voltage V_{RC}(k).

Determination of Convergence

Next, a description is made of convergence determination by convergence determiner 25.

Convergence determiner 25 mainly performs determination based on the battery characteristics and determination by a state estimation internal parameter.

Determination of Abnormal Environment

The determination based on the battery characteristics first includes the determination of an abnormal environment. An abnormal environment refers to an environment that cannot be handled by the equivalent circuit model of secondary battery 100 in a state estimation method. To determine an abnormal environment, one or more of the following conditions can be included for example.
Temperature of secondary battery>Threshold Ta
   Here, threshold Ta represents an abnormally high temperature.
Temperature of secondary battery<Threshold Tb
   Here, threshold Tb represents an abnormally low temperature.
DC internal resistance of secondary battery>Threshold Rth
   Here, threshold Rth represents a DC internal resistance of a deteriorated secondary battery.
Lowest voltage during cranking<Threshold Vth
   Here, threshold Vth represents the lowest voltage during cranking of deteriorated secondary battery 100. “During cranking” refers to “when a starter motor is driven by the power of secondary battery 100 when an engine equipped to a vehicle is started, when secondary battery 100 outputs high electric power.”

Convergence determiner 25 determines that the state estimation SOC is not in convergence if at least one of the determination results of an abnormal environment indicates yes.

Determination of being in Constant-Voltage Charging

The determination based on the battery characteristics secondly includes determination of being in constant-voltage charging.

It is constant-voltage charging determiner 24 that makes the determination of being in constant-voltage charging.

To determine being in constant-voltage charging, one or more of the following conditions can be included for example.
First one: following three conditions are satisfied at the same time:
A difference between the maximum and minimum values among past N points in a current variation amount (dI)<Threshold dIth,
A difference between the maximum and minimum values among the past N points in a voltage variation amount(dV)<Threshold dVth, and,
Voltage>Threshold Vcv
   Here, the current variation amount represents the amount of change in a charge/discharge current of secondary battery 100. The voltage variation amount represents the amount of change in an inter-terminal voltage of secondary battery 100. Each of the variation amounts may be either that per sampling period or that per given time. The difference between the maximum and minimum values among the past N points represents an example variation in each of the amounts. The number of past N points, threshold dIth, and threshold dVth are set so that they show a constant-voltage charging in which state estimation does not tend to converge. Threshold Vcv is a voltage value indicating constant-voltage charging.
Second one: a state of “Charging current<Threshold Ith” continues for given time or longer

Here, threshold Ith is a charging current indicating an overcharge.
Third one: Current-integration SOC<Threshold SOCth

Here, threshold SOCth indicates a value (e.g., 60% or less) at which charging is required.

During the constant-voltage charging, the current variation amount and voltage variation amount fluctuate slightly. In state estimation of secondary battery 100, current values and voltage values are used as detected values, and thus small changes in current values and voltage values cause an estimated value of an internal state of secondary battery 100 to be hard to converge. In such a case, there is a high possibility that the state-of-charge value calculated by state estimation contains a large error.

Constant-voltage charging determiner 24 determines being in constant-voltage charging based on the above-described criterion expression and sends the result to convergence determiner 25. Convergence determiner 25 determines as the state estimation is non-convergent when in constant-voltage charging.

In determining being in constant-voltage charging, each of the current and voltage is an example of a given charging parameter according to the disclosure, and variation in the amount of change in each of current and voltage less than a threshold indicates that the amount of change in a given charging parameter is less than a given threshold. The case where the state in which the charging current is less than threshold Ith (indicating overcharge) continues for given time or longer indicates that the charging current stays below threshold Ith for the given time or longer, which means that change in the given charging parameter is smaller than the given threshold. When the current-integration SOC indicates that charging is required, constant-voltage charging continues, which indirectly indicates the amount of change in voltage or current falls a given threshold or below.

The above-described criterion expression “Current-integration SOC<Threshold SOCth” may be included in the determination of the abnormal environment.

Determination Based on Internal Parameter of State Estimation

In the state estimation, the internal parameter of secondary battery 100 is estimated while the dispersion of errors in estimated values is being calculated. Hence, convergence determiner 25 determines to what extent the estimated value has converged based on the dispersion of errors. In the determination based on the internal parameter, one or more of the following conditions can be included for example.
Norm of estimation error covariance matrix<Threshold α
At least one of diagonal elements of estimation error covariance matrix<Threshold β

Here, thresholds α and β are set to values such that the estimated value can be regarded as having converged. Diagonal elements of the estimation error covariance matrix include an element corresponding to a state-of-charge, and thus it is reasonable that at least the element corresponding to a state-of-charge is compared. However, if the estimated value of another diagonal element has converged, the estimated value of the state-of-charge has converged in many cases, and thus a component other than the element corresponding to a state-of-charge may be compared.

The above-described example can be applied to state estimation using an iterative least squares technique and to state estimation using an adaptive filter such as a Kalman filter. However, other state estimation methods such as a state estimation using a particle filter and a learning method using a neural network can also calculate the variation of errors in an estimated value in the same way. Hence, the same determination can be made using the variation as an internal parameter.

In state estimation using a particle filter, one or more of the following conditions can be included, for example.
The dispersion or standard deviation of all the particles (a sampling value of a state variable)<Threshold α1
The difference between the maximum and minimum values of the state variables of all the particles<Threshold β1

For a neural network, the next condition can be included.
The derivative of an output error function<Threshold α2

Convergence determiner 25 determines that the state estimation has converged if the determination based on the above-described internal parameter indicates yes and at the same time no other conditions indicating non-convergence are satisfied.

Determination Based on the Comparison of an Estimation Result with an Actually Measured Value

Convergence determiner 25 may further determine whether or not the state estimation is in non-convergence based on the comparison of the value of the internal parameter estimated by state estimation SOC calculator 22; with the value based on the detection result of detector 11. The value based on an actually measured value contains an error, and thus the determination based on this comparison is merely determination to check for a value unusually different from the value based on an actually measured value. If a value unusually different is found, the estimated value can contain a large error, and thus the estimated value can be determined being in non-convergence.

In state estimation based on an estimation result and an actually measured value, one or more of the following conditions can be included, for example.
Variation in a detected value and an estimated value of an inter-terminal voltage of secondary battery 100<Threshold α3

Here, the variation can be represented by a square root error, standard deviation, dispersion, or error average value, for example. Threshold α3 is set to a value large enough to identify an unusually large variation.
   |Current-integration SOC−State estimation SOC|<Threshold β2

Here, threshold β2 is set to a value large enough to identify an unusually large difference.

Convergence determiner 25 determines as the state estimation is non-convergent if each of the above-described criterion expressions is no.

Process Flow

Subsequently, a description is made of an example of the overall process performed by state-of-charge estimating device 1.

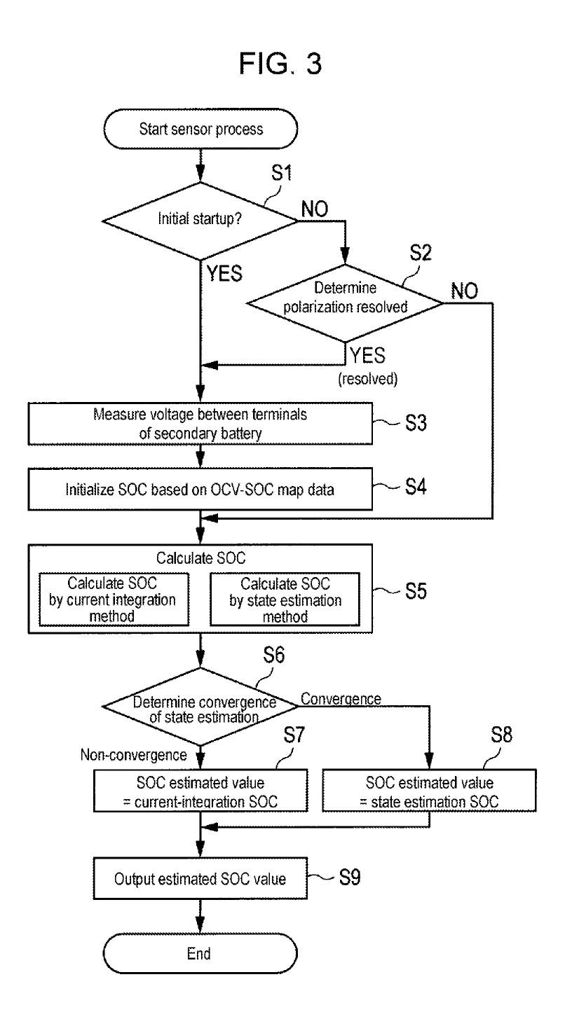

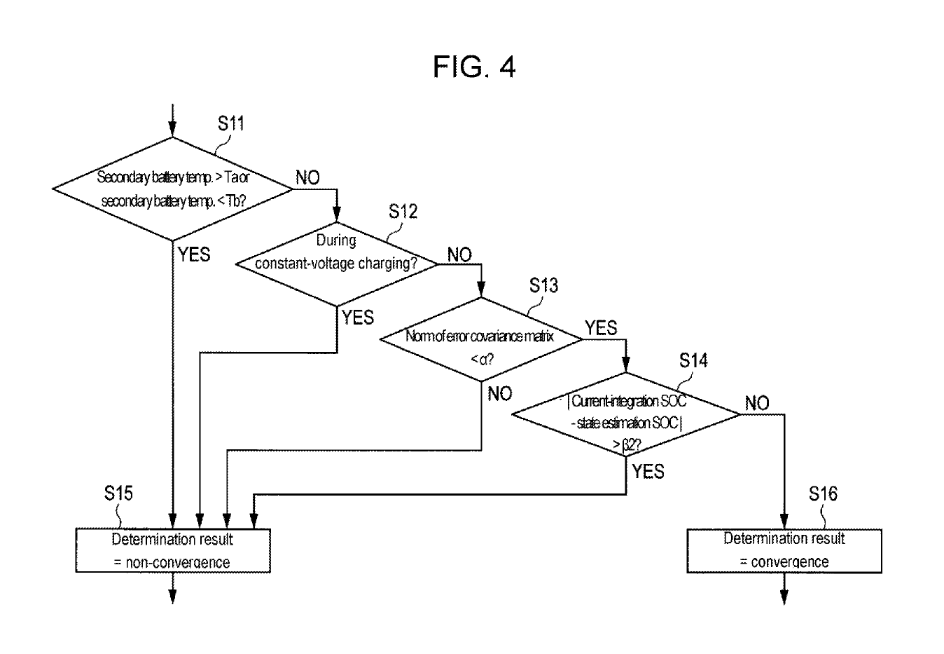

FIG. 3 is a flowchart illustrating the process flow performed by the state-of-charge estimating device. FIG. 4 is a flowchart illustrating details of the steps for determining the convergence of state estimation.

The process flow of FIG. 3 is executed at each timing for sampling a charge/discharge current and a voltage of secondary battery 100 by detector 11.

When the process flow is started, whether or not it is an initial startup is first determined (step S1). If it is the initial startup, detector 11 measures an inter-terminal voltage of secondary battery 100 (step S3), and obtains an initial value of the state-of-charge (SOC) based on map data representing the relationship between open-circuit voltages (OCV) and values of state-of-charge (SOC). Then, current-integration SOC calculator 21 and state estimation SOC calculator 22 are initialized (step S4). The determination of step S1 may be performed by current-integration SOC calculator 21 and state estimation SOC calculator 22. Alternatively, it may be performed by another centralized control unit.

If it is determined that it is not an initial startup in step S1, determination is made whether or not the polarization of secondary battery 100 has been resolved (step S2). Here, if secondary battery 100 is left for sufficient time without being charged or discharged for example, it is determined that the polarization has been resolved. If it is determined that the polarization has been resolved, steps S3 and S4 related to initialization are performed, and then the process proceeds to step S5; otherwise, steps S3 and S4 related to initialization are skipped and the process proceeds to step S5. The determination of step S2 may be performed by current-integration SOC calculator 21 and state estimation SOC calculator 22. Alternatively, it may be performed by another centralized control unit.

In step S5, current-integration SOC calculator 21 and state estimation SOC calculator 22 calculate respective state-of-charge values using the value detected by detector 11.

In step S6, convergence determiner 25 determines the convergence of state estimation by state estimation SOC calculator 22.

The determination of convergence in step S6 is achieved by the steps shown in FIG. 4. The process flow of FIG. 4 shows an example of the convergence determination process, but does not limit the process by the convergence determiner of the disclosure. The criterion expression used in each step of FIG. 4 can be changed to another criterion expression, or another criterion expression can be added as shown in the description of the determination of convergence.

In the convergence determination step, convergence determiner 25 first determines an abnormal environment described under “Determination of convergence” (step S11). In the example of FIG. 4, convergence determiner 25 determines in step S11 whether or not one of the following conditions is satisfied: that the temperature of secondary battery 100 is higher than threshold Ta indicating an extremely high temperature, and that the temperature of secondary battery 100 is lower than threshold Tb indicating an extremely low temperature. If the determination result is yes, convergence determiner 25 regards the determination result of the estimation state as non-convergence (step S15).

If the result of determining an abnormal environment is no, convergence determiner 25 then determines whether or not the battery is in constant-voltage charging (step S12). For example, constant-voltage charging determiner 24 determines whether or not the following three conditions are satisfied at the same time: that the difference between the maximum and minimum values among the past N points in the current variation amount (dI) is smaller than threshold dIth; that the difference between the maximum and minimum values among the past N points in the voltage variation amount (dV) is smaller than threshold dVth; and that the inter-terminal voltage of secondary battery 100 is higher than threshold Vcv indicating charging, and sends the determination result to convergence determiner 25. Upon receiving the determination result of the constant-voltage charging, convergence determiner 25 regards the determination result of the estimation state as non-convergence (step S15).

If the result of determining whether or not the battery is in the constant-voltage charging is no, convergence determiner 25 next performs determination based on the internal parameter from state estimation SOC calculator 22 (step S13). In the example of FIG. 4, convergence determiner 25 calculates a norm of error covariance matrix P(k) received from state estimation SOC calculator 22 and determines whether or not the norm is smaller than threshold α. Convergence determiner 25, if the determination result of step S13 is no, regards the determination result of the estimation state as non-convergence (step S15).

If the determination result of step S13 is yes, convergence determiner 25 next performs determination based on the comparison of an estimated value with an actually measured value (step S14). In the example of FIG. 4, it is determined whether or not the absolute value of the difference between the current-integration SOC and the state estimation SOC is larger than threshold β2. Threshold β2 is set to a value indicating both are unusually different from each other. Convergence determiner 25, if the determination result of step S14 is yes, regards the determination result of the estimation state as non-convergence (step S15). Otherwise, Convergence determiner 25 regards the determination result of the estimation state as convergence (step S16).

The determination result of step S15 and that of step S16 become the result of the determination step of step S6 in FIG. 3.

If the determination result of step S6 is non-convergence, SOC selector 26 selects the current-integration SOC calculated by current-integration SOC calculator 21 as an SOC estimated value (step S7).

Meanwhile, if the determination result of step S6 is convergence, SOC selector 26 selects the state estimation SOC calculated by state estimation SOC calculator 22 as an SOC estimated value (step S8).

SOC selector 26 outputs the state estimation SOC selected in step S7 or the current-integration SOC selected instep S8 as an SOC estimated value (step S9).

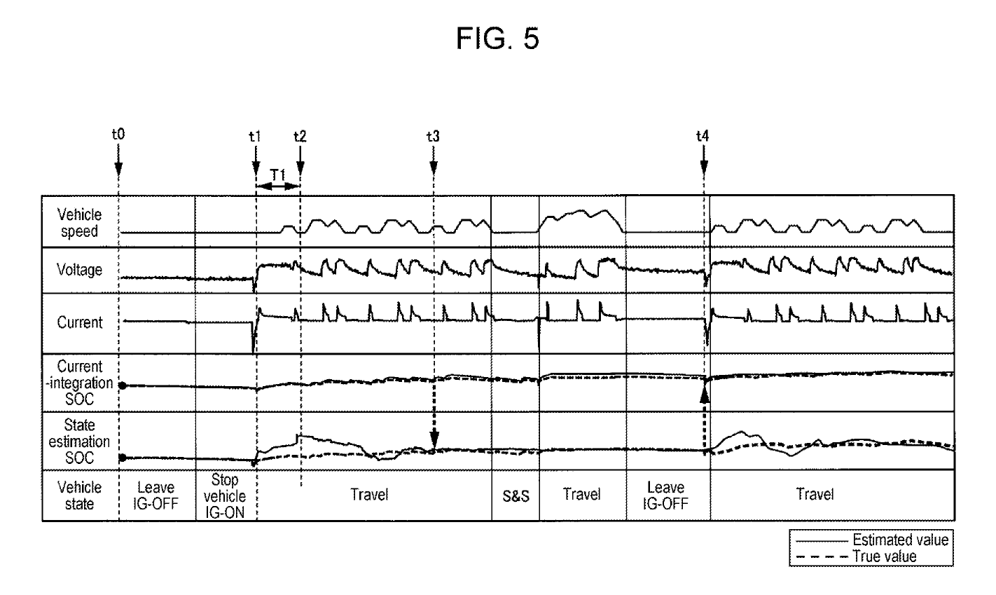

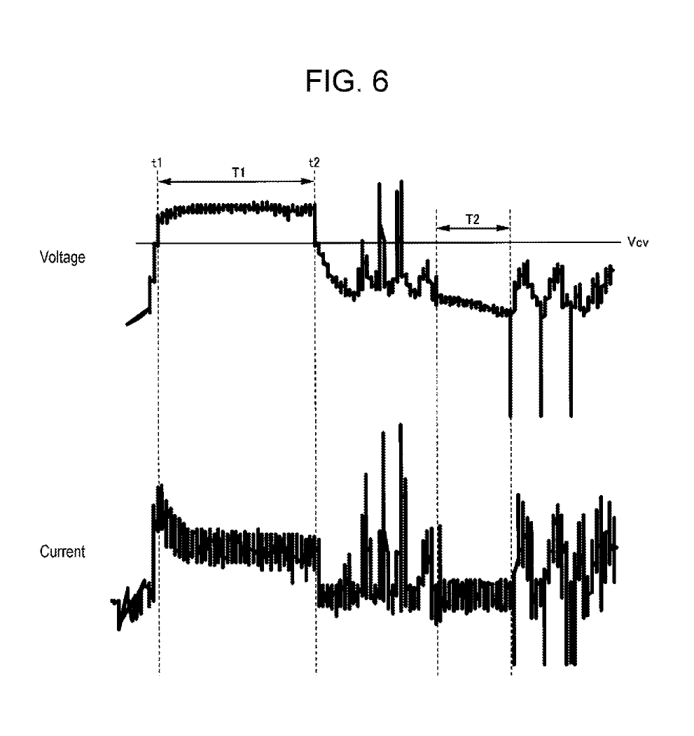

FIG. 5 is a time chart illustrating operation of the state-of-charge estimating device. FIG. 6 is a time chart showing details of the determination period of constant-voltage charging.

According to the process flows of FIGS. 3 and 4, the state estimation SOC and the current-integration SOC are switched to each other as shown by the time chart of

FIG. 5, allowing an SOC estimated value with a small error to be output.

Timing t1 in FIG. 5 corresponds to a timing when state-of-charge estimating device 1 is started up or when secondary battery 100 is replaced for example. At timing t1, an initial value of a state-of-charge is given to current-integration SOC calculator 21, and an initial value of state vector x(k) and an initial value of a dispersion value are given to state estimation SOC calculator 22.

At initialization, the polarization of secondary battery 100 has a small effect, and a current-integration SOC contains a relatively small error from the true value.

As shown by the period between timings t0 and t1 in FIG. 5, secondary battery 100 only continues outputting a small discharging current during a period of ignition off of a vehicle from initialization, and during a period in which a vehicle keeps stopping. During those periods, the norm of error covariance matrix P(k) calculated by state estimation SOC calculator 22 stays at a level not lower than the initial value, and thus the determination result of convergence determiner 25 is non-convergence. Hence, SOC selector 26 outputs a current-integration SOC with a small error in those periods.

As shown by the period between timings t1 and t2 in FIG. 5, during the period in which the vehicle starts travelling after the ignition has been turned on, the starter motor starts up to cause a large amount of discharge from secondary battery 100. Then, the alternator is driven to cause constant-voltage charging for secondary battery 100. Period T1 in FIG. 5 indicates a period of the constant-voltage charging.

For example, when secondary battery 100 discharges a large amount of power, the charge/discharge current and inter-terminal voltage largely fluctuate, thereby the state estimation of secondary battery 100 by state estimation SOC calculator 22 proceeds. Hence, the norm of error covariance matrix P(k) sometimes decreases temporarily. However, immediately after the state estimation has proceeded, the state estimation is not yet in convergence. Furthermore, secondary battery 100 starts constant-voltage charging at this timing, thus, fluctuations in the charge/discharge current and inter-terminal voltage of secondary battery 100 decease and the state estimation recedes from convergence.

Even if the norm of error covariance matrix P(k) temporarily represents a small value during such a period, convergence determiner 25 determines that the state estimation is in non-convergence from the determination of being in constant-voltage charging. This prevents a state estimation SOC with a large error from being output as an SOC estimated value, and a current-integration SOC with a small error is output.

As shown in FIG. 6, the state if being in constant-voltage charging is determined if the following conditions are satisfied: (1) the maximum variation in temporal change of a current is equal to or less than threshold dIth; (2) the maximum variation in temporal change of a voltage is equal to or less than threshold dVth, (3) and at the same time the voltage is equal to or higher than threshold V_{CV}, which indicates the battery is being charged. Even if conditions (1) and (2) are satisfied except for condition (3), an appropriate period (e.g., period T2) is present during discharging; however, the condition (3) prevents such a period from being unintentionally determined being in constant-voltage charging.

Subsequently, as shown by the period between timings t2 and t4 in FIG. 5, discharge and charge repeated during travel of a vehicle causes the state estimation to converge, and the state estimation SOC approaches the true value. This also influences the polarization of secondary battery 100, resulting in a relatively large error in the current-integration SOC. When the state estimation is in convergence, the norm of error covariance matrix P(k) calculated by state estimation SOC calculator 22 deceases, and accordingly convergence determiner 25 determines as the state estimation is convergent. FIG. 5 shows that the convergence of this state estimation is determined at timing t3. As a result, SOC selector 26 changes the selection, and state-of-charge estimating device 1 outputs the state estimation SOC as an SOC estimated value.

As shown in a stage before timing t4, if secondary battery 100 is left for a long time while the vehicle remains stopped, for example, step S2 of FIG. 3 determines that the polarization has been resolved, and thus current-integration SOC calculator 21 and state estimation SOC calculator 22 are initialized again. The initialization also initializes the dispersion value of state estimation SOC calculator 22, and thus the norm of error covariance matrix P(k) increases again, thus convergence determiner 25 determines the non-convergence of the state estimation. As a result, a current-integration SOC is output.

As described above, according to state-of-charge estimating device 1 of the embodiment, respective state-of-charge (SOC) values are calculated by a current integration method and by a state estimation method, and one of the estimated SOC values is selected and output according to the determination result of the convergence of the state estimation. Hence, a current-integration SOC is output during a period in which the current integration method has a smaller error; a state estimation SOC is output during a period in which the state estimation method has a smaller error. Consequently, a state-of-charge can be estimated with a small error.

According to state-of-charge estimating device 1 of the embodiment, the state estimation is determined non-convergence if a state being in constant-voltage charging is detected. This prevents an erroneous determination that the state estimation has converged during constant-voltage charging when the current and voltage variation amounts are small and the state estimation is hard to convergence. Hence, a state-of-charge can be estimated with high accuracy.

In the above-described embodiment, a state space estimation method using a Kalman filter is shown as an example of a state estimation method; however, a state space estimation method using an iterative least squares technique, a state space estimation method using an adaptive filter such as a particle filter, or a state estimation method using a learning method such as a neural network may be employed.

In the above-described embodiment, as a method of detecting the state being in constant-voltage charging, the case is shown where an inter-terminal voltage of secondary battery 100 is higher than threshold Vcv indicating constant-voltage charging, and the variations of the amount of change in current and of the amount of change in voltage are smaller than the respective thresholds; however, the detection method is changeable as appropriate. For example, a state being in constant-voltage charging may be determined by detecting that the current falls within a given range indicating constant-voltage charging and the variation of the amount of change in voltage is smaller than a threshold at the same time.

In the above-described embodiment, the description is made of a device and a method that estimate a state-of-charge of a secondary battery incorporated in a vehicle; however, the device and the method may be applied to a secondary battery incorporated in an object other than a vehicle. Besides, the details described in the embodiment can be changed as appropriate within a scope that does not deviate from the gist of the present disclosure.

### INDUSTRIAL APPLICABILITY

The present disclosure is usable for a device that estimates a state-of-charge of a secondary battery.

### REFERENCE MARKS IN THE DRAWINGS

1 state-of-charge estimating device
11 detector
20 calculation device
21 current-integration SOC calculator
22 state estimation SOC calculator
23 DC internal resistance detector
24 constant-voltage charging determiner
25 convergence determiner
26 SOC selector
100 secondary battery

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A secondary battery state-of-charge estimating device comprising:
a detector configured to detect a charge/discharge current and a voltage between terminals of a secondary battery;
a current-integration SOC calculator configured to calculate a state-of-charge value of the secondary battery based on a detection result of the detector by a current integration method;
a state estimation SOC calculator configured to calculate a state-of-charge value of the secondary battery based on a detection result of the detector by a state estimation method;
a convergence determiner configured to determine convergence of state estimation by the state estimation SOC calculator; and
an SOC selector configured to select a state-of-charge of the secondary battery from the state-of-charge value calculated by the current-integration SOC calculator and the state-of-charge value calculated by the state estimation SOC calculator, according to a determination result of the convergence determiner,
wherein the convergence determiner determines as the state estimation is non-convergent when the convergence determiner determines that the secondary battery is being charged and change of a given charging parameter is smaller than a given threshold.

2. The secondary battery SOC estimating device according to claim 1, wherein the convergence determiner determines as the state estimation is non-convergent when the convergence determiner determines that
variation of an amount of current change of the secondary battery is smaller than a first threshold,
variation of an amount of voltage change of the secondary battery is smaller than a second threshold, and
the voltage between terminals of the secondary battery is higher than a third threshold indicating charging.

3. The secondary battery SOC estimating device according to claim 1, wherein the convergence determiner determines as the state estimation is non-convergent when the convergence determiner determines that a current of the secondary battery smaller than a fourth threshold indicating overcharge has continued for a given time.

4. The secondary battery SOC estimating device according to claim 1, wherein the convergence determiner determines as the state estimation is non-convergent when the secondary battery is being charged and an amount of change of the given charging parameter within a given time is equal to or smaller than the given threshold indicating constant-voltage charging.

5. The secondary battery SOC estimating device according to claim 1,
wherein the state estimation SOC calculator estimates the state-of-charge value of the secondary battery by performing estimated calculation including calculation of dispersion of an error of an estimated value, and
wherein the convergence determiner determines the convergence based on a value of the dispersion.

6. The secondary battery SOC estimating device according to claim 5,
wherein the state estimation SOC calculator estimates the state-of-charge value of the secondary battery by performing estimated calculation including calculation of an estimation error covariance matrix, using one of a Kalman filter and an iterative least squares technique, as the calculation of dispersion of an error, and
wherein the convergence determiner determines as the state estimation is convergent when a norm of the estimation error covariance matrix is smaller than a predetermined fifth threshold and the conditions of determining as non-convergence are not satisfied.

7. The secondary battery SOC estimating device according to claim 5,
wherein the state estimation SOC calculator estimates the state-of-charge value of the secondary battery by performing estimated calculation including calculation of an estimation error covariance matrix, using one of a Kalman filter and an iterative least squares technique, as the calculation of dispersion of an error, and
wherein the convergence determiner determines as the state estimation is convergent when a value of at least one diagonal element of the estimation error covariance matrix is smaller than a predetermined sixth threshold and the conditions of determining non-convergence are not satisfied.

8. The secondary battery SOC estimating device according to claim 5, wherein the convergence determiner determines as the state estimation is non-convergent further based on comparison of an estimated value calculated by the state estimation SOC calculator with an actually measured value based on detection by the detector.

9. The secondary battery SOC estimating device according to claim 1,
wherein the convergence determiner determines as the state estimation is non-convergent further based on comparison of an estimated value calculated by the state estimation SOC calculator with an actually measured value based on detection by the detector.

10. The secondary battery SOC estimating device according to claim 9, wherein the convergence determiner determines as the state estimation is non-convergent
when one of errors is larger than a predetermined seventh threshold, where the errors consists of:
an error between an actually measured voltage between terminals of the secondary battery detected by the detector and an voltage between terminals of the secondary battery calculated by the state estimation SOC calculator,
an error between an actually measured value of the charge current and an estimated value of the charge current, and
an error between an actually measured value of the discharge current and an estimated value of the discharge current.

11. The secondary battery SOC estimating device according to claim 9, wherein the convergence determiner determines as the state estimation is non-convergent when a difference between an estimated value of a state-of-charge calculated by the state estimation SOC calculator and a state-of-charge calculated by the current-integration SOC calculator as the actually measured value is larger than a predetermined eighth threshold.

12. A secondary battery SOC estimating method comprising:
detecting a charge or discharge current and a voltage between terminals of a secondary battery;
calculating a state-of-charge value of the secondary battery based on the detected charge/discharge current and on the detected voltage between terminals, by a current integration method;
calculating a state-of-charge value of the secondary battery based on the detected charge/discharge current and on the detected voltage between terminals, by a state estimation method;
determining convergence of state estimation when calculating a state-of-charge of the secondary battery; and
selecting a state-of-charge of the secondary battery from the state-of-charge value calculated by the current integration method and the state-of-charge value calculated by the state estimation method, according to the determination result of the convergence,
wherein when determining convergence, the state estimation is determined as non-convergent in a case where the secondary battery is being charged and change of a given charging parameter is smaller than a given threshold.

13. The secondary battery SOC estimating device according to claim 2,
wherein the state estimation SOC calculator estimates the state-of-charge value of the secondary battery by performing estimated calculation including calculation of dispersion of an error of an estimated value, and
wherein the convergence determiner determines the convergence based on a value of the dispersion.

14. The secondary battery SOC estimating device according to claim 13,
wherein the state estimation SOC calculator estimates the state-of-charge value of the secondary battery by performing estimated calculation including calculation of an estimation error covariance matrix, using one of a Kalman filter and an iterative least squares technique, as the calculation of dispersion of an error, and
wherein the convergence determiner determines as the state estimation is convergent when a norm of the estimation error covariance matrix is smaller than a predetermined fifth threshold and the conditions of determining as non-convergence are not satisfied.

15. The secondary battery SOC estimating device according to claim 13,
wherein the state estimation SOC calculator estimates the state-of-charge value of the secondary battery by performing estimated calculation including calculation of an estimation error covariance matrix, using one of a Kalman filter and an iterative least squares technique, as the calculation of dispersion of an error, and
wherein the convergence determiner determines as the state estimation is convergent when a value of at least one diagonal element of the estimation error covariance matrix is smaller than a predetermined sixth threshold and the conditions of determining non-convergence are not satisfied.

16. The secondary battery SOC estimating device according to claim 3,
wherein the state estimation SOC calculator estimates the state-of-charge value of the secondary battery by performing estimated calculation including calculation of dispersion of an error of an estimated value, and
wherein the convergence determiner determines the convergence based on a value of the dispersion.

17. The secondary battery SOC estimating device according to claim 16,
wherein the state estimation SOC calculator estimates the state-of-charge value of the secondary battery by performing estimated calculation including calculation of an estimation error covariance matrix, using one of a Kalman filter and an iterative least squares technique, as the calculation of dispersion of an error, and
wherein the convergence determiner determines as the state estimation is convergent when a norm of the estimation error covariance matrix is smaller than a predetermined fifth threshold and the conditions of determining as non-convergence are not satisfied.

18. The secondary battery SOC estimating device according to claim 16,
wherein the state estimation SOC calculator estimates the state-of-charge value of the secondary battery by performing estimated calculation including calculation of an estimation error covariance matrix, using one of a Kalman filter and an iterative least squares technique, as the calculation of dispersion of an error, and
wherein the convergence determiner determines as the state estimation is convergent when a value of at least one diagonal element of the estimation error covariance matrix is smaller than a predetermined sixth threshold and the conditions of determining non-convergence are not satisfied.

19. The secondary battery SOC estimating device according to claim 4,
wherein the state estimation SOC calculator estimates the state-of-charge value of the secondary battery by performing estimated calculation including calculation of dispersion of an error of an estimated value, and
wherein the convergence determiner determines the convergence based on a value of the dispersion.

20. The secondary battery SOC estimating device according to claim 19,
wherein the state estimation SOC calculator estimates the state-of-charge value of the secondary battery by performing estimated calculation including calculation of an estimation error covariance matrix, using one of a Kalman filter and an iterative least squares technique, as the calculation of dispersion of an error, and
wherein the convergence determiner determines as the state estimation is convergent when a norm of the estimation error covariance matrix is smaller than a predetermined fifth threshold and the conditions of determining as non-convergence are not satisfied.

21. The secondary battery SOC estimating device according to claim 19,
wherein the state estimation SOC calculator estimates the state-of-charge value of the secondary battery by performing estimated calculation including calculation of an estimation error covariance matrix, using one of a Kalman filter and an iterative least squares technique, as the calculation of dispersion of an error, and
wherein the convergence determiner determines as the state estimation is convergent when a value of at least one diagonal element of the estimation error covariance matrix is smaller than a predetermined sixth threshold and the conditions of determining non-convergence are not satisfied.
